(19) United States
(12) Patent Application Publication
(10) Pub. No.: US 2007/0018184 A1
(43) Pub. Date: Jan. 25, 2007

(54) Light emitting diodes with high light extraction and high reflectivity

(75) Inventors: Karl W. Beeson, Princeton, NJ (US); Scott M. Zimmerman, Baskin Ridge, NJ (US); William R. Livesay, San Diego, CA (US)

Correspondence Address: William Propp, Esq.;Goldeneye, Inc., Suite 233, 9747 Businesspark Avenue, San Diego, CA, 92131, US

(73) Assignee: Goldeneye, Inc.

(21) Appl. No.: 11/389,201

(22) Filed: Mar. 24, 2006

Related U.S. Application Data
(63) Continuation-in-part of application No. 11/185,996, filed on Jul. 20, 2005.

(51) Int. Cl. H01L 33/00

(52) U.S. Cl. 257/98

(57) ABSTRACT

The invention is a light emitting diode that exhibits high reflectivity to externally incident light and high extraction efficiency for internally generated light. The light emitting diode includes a first reflecting electrode that reflects both externally incident light and internally generated light. The first reflecting electrode can be a metal layer; or a transparent layer and a metal layer; or a transparent layer and a metal layer with a plurality of metal contacts extending from the reflecting metal layer through the transparent layer. A multi-layer semiconductor structure is in contact with the first reflecting layer and has an active region that emits the internally generated light in an emitting wavelength range. The multi-layer semiconductor structure has an absorption coefficient less than 50 cm⁻¹. A second reflecting electrode underlies the multi-layer semiconductor structure and reflects both the externally incident light and the internally generated light. The second reflecting electrode can be a first transparent layer and a reflecting metal layer; or a second transparent layer, a first transparent layer and a reflecting metal layer; or a second transparent layer, a first transparent layer and a reflecting metal layer with a plurality of metal contacts extending from the reflecting metal layer through the first transparent layer to the second transparent layer. An array of light extracting elements extends at least part way through the multi-layer semiconductor structure and improves the extraction efficiency for the internally generated light.

### CROSS REFERENCES TO RELATED APPLICATIONS

This application is a continuation-in-part of U.S. patent application Ser. No. 11/185,996 entitled “LIGHT EMITTING DIODES WITH IMPROVED LIGHT EXTRACTION AND REFLECTIVITY,” which was filed Jul. 20, 2005, and which is herein incorporated by reference. This application is also related to U.S. patent application Ser. No. 10/952,112 entitled “LIGHT EMITTING DIODES EXHIBITING BOTH HIGH REFLECTIVITY AND HIGH LIGHT EXTRACTION”, U.S. Pat. No. 6,869,206 and U.S. Pat. No. 6,960,872, all of which are herein incorporated by reference.

### TECHNICAL FIELD

The present invention relates to light emitting diodes that exhibit both high light extraction efficiency and high reflectivity to externally incident light.

### BACKGROUND

Light emitting diodes (LEDs) are rapidly replacing incandescent and fluorescent light sources for many illumination applications. LEDs emit light in the ultraviolet, visible and infrared regions of the optical spectrum. Gallium nitride (GaN) based LEDs, for example, emit light in the ultraviolet, blue, cyan and green spectral regions. However, there are three critical issues that currently restrict LED deployment in some situations. The first issue is that many types of LEDs typically have low external quantum efficiencies. When the external quantum efficiency of an LED is low, the LED produces fewer lumens per watt than a standard fluorescent lamp, thereby slowing the changeover to LEDs in new light source designs.

The second issue is that LEDs lack sufficient brightness for demanding applications that now use arc lamp sources. Applications such as large area projection displays require high-brightness light sources that can emit several watts of optical power into a source area of less than 10 mm². Present LEDs do not achieve this level of output power in such a small area. One reason for the insufficient brightness is the low external quantum efficiency of the LEDs. The two effects of low quantum efficiency and low output power are related.

Third, the reflectivity of an LED to externally incident light is critically important for applications where some of the internally generated light emitted into the external environment by the LED is reflected or recycled back to the LED. For example, both U.S. Pat. No. 6,869,206 by Zimmerman and Beeson and U.S. Pat. No. 6,960,872 by Beeson and Zimmerman disclose that light recycling can be utilized to construct enhanced brightness LED optical illumination systems. In the above-mentioned patent and patent application, the LEDs are located inside light reflecting cavities or light recycling envelopes and light is reflected off the surfaces of the LEDs in order to achieve the enhanced brightness. If the LEDs have poor reflectivity to externally incident light, some of the reflected light will be absorbed by the LEDs and reduce the overall efficiencies of the light sources.

The external quantum efficiency of an LED is equal to the internal quantum efficiency for converting electrical energy into photons multiplied by the light extraction efficiency. The internal quantum efficiency, in turn, is dependent on many factors including the device structure as well as the electrical and optical properties of the LED semiconductor materials.

The light extraction efficiency of an LED die is strongly dependent on the refractive index of the LED relative to its surroundings, to the shape of the die, and to the presence or absence of light extracting elements that can enhance light extraction. For example, increasing the refractive index of the LED relative to its surroundings will decrease the light extraction efficiency. An LED die with flat external sides and right angles to its shape will have lower light extraction efficiency than an LED with beveled sides. An LED with no light extracting elements on the output surface will have lower light extraction efficiency than an LED that has additional light extracting elements on the output surface.

Solid-state LEDs are generally constructed from semiconductor materials that have a high refractive index (n>2). For example, GaN-based light emitting materials have a refractive index of approximately 2.5.

If the LED die has a refractive index n_{die}, has flat external surfaces, and is in contact with an external material, such as air or a polymer overcoat, that has a refractive index next, only light that has an angle less than the critical angle will exit from the die. The remainder of the light will undergo total internal reflection at the inside surfaces of the die and remain inside the die. The critical angle θ_{c} inside the die is given by
θ_{c}=arcsin (nₓₜ/n_{die}), [Equation 1]
where θ_{c} is measured relative to a direction perpendicular to the LED output surface. For example, if the external material is air with a refractive index nₑₓₜ of 1.00 and the refractive index n_{die} is 2.5, the critical angle is approximately 24 degrees. Only light having incident angles between zero and 24 degrees will exit from the LED die. The majority of the light generated by the active region of the LED will strike the surface interface at angles between 24 degrees and 90 degrees and will undergo total internal reflection. The light that is totally internally reflected will remain in the die until it is either absorbed or until it reaches another surface that may allow the light to exit.

The absorption of light by the LED die can also strongly influence the overall efficiency of the LED. The transmission T of light that is transmitted through an optical pathlength L of an LED die having an absorption coefficient a is given by
T=e^{-αL}. [Equation 2]
If the absorption for a pathlength L is desired to be less than 20%, for example, or, conversely, the transmission T is desired to be greater than 80%, then the quantity αL in Equation 2 should be about 0.2 or less. If α=50 cm⁻¹, for example, then L should be less than about 0.004 centimeters or 40 microns in order to keep the absorption less than about 20%. Since many LED die materials have semiconductor layers with absorption coefficients higher than 50 cm⁻¹ and since many LED dies have lateral dimensions of 300 microns or larger, a large fraction of the light generated by the die may be absorbed inside the die before it can be extracted.

Some LED dies incorporate a growth substrate, such as sapphire or silicon carbide, upon which the semiconductor layers are fabricated. U.S. Patent Application Serial No. 20050023550 discloses how the absorption coefficient of the growth substrate as well as the thickness of the growth substrate can affect the light extraction efficiency of an LED die. If the growth substrate remains as part of the LED die, either reducing the absorption coefficient of the growth substrate or reducing the thickness of the growth substrate increases the light extraction efficiency. However, U.S. Patent Application Serial No. 20050023550 does not disclose how the absorption coefficient of the semiconductor layers affects the light extraction efficiency of the LED die or the reflectivity of the LED die to externally incident light.

Many ideas have been proposed for increasing the light extraction efficiency of LEDs. These ideas include forming angled (beveled) edges on the die, adding non-planar surface structures to the die, roughening at least one surface of the die, and encapsulating the die in a lens that has a refractive index intermediate between the refractive index of the die n_{die} and the refractive index of air.

For example, it is a common practice to enclose the LED within a hemispherical lens or a side-emitting lens in order to improve the light extraction efficiency. LEDs with side emitting lenses are disclosed in U.S. Pat. No. 6,679,621 and U.S. Pat. No. 6,647,199. A typical hemispherical lens or side-emitting lens has a refractive index of approximately 1.5. More light can exit from the LED die through the lens than can exit directly into air from the LED die in the absence of the lens. Furthermore, if the lens is relatively large with respect to the LED die, light that exits the die into the lens will be directly approximately perpendicular to the output surface of the lens and will readily exit through the lens. However, the typical radius of the hemispherical lens or the height of the side-emitting lens in such devices is 6 mm or larger. This relatively large size prevents the use of the lens devices in, for example, ultra-thin liquid crystal display (LCD) backlight structures that are thinner than about 6 mm. In order to produce ultra-thin illumination systems, it would be desirable to eliminate the lens but still retain high light extraction efficiency. U.S. Pat. No. 6,679,621 and U.S. Pat. No. 6,647,199 do not disclose how the absorption coefficient of the semiconductor layers affects the light extraction efficiency of the LED die or the reflectivity of the LED die to externally incident light.

U.S. Patent Application Ser. No. 20020123164 discloses using a series of grooves or holes fabricated in the growth substrate portion of the die as light extracting elements. The growth substrate portion of the die can be, for example, the silicon carbide or sapphire substrate portion of a die onto which the GaN-based semiconductor layers are grown. However, in U.S. Patent Application Ser. No. 20020123164 the grooves or holes do not extend into the semiconductor layers. If the substrate is sapphire, which has a lower index of refraction than GaN, much of the light can still undergo total internal reflection at the sapphire-semiconductor interface and travel relatively long distances within the semiconductor layers before reaching the edge of the die. U.S. Patent Application Serial. No. 20020123164 does not disclose how the absorption coefficient of the semiconductor layers affects the light extraction efficiency of the LED die or the reflectivity of the LED die.

U.S. Pat. No. 6,410,942 discloses the formation of arrays of micro-LEDs on a common growth substrate to reduce the distance that emitted light must travel in the LED die before exiting the LED. Micro-LEDs are formed by etching trenches or holes through the semiconductor layers that are fabricated on the growth substrate. Trenches are normally etched between LEDs on an array to electrically isolate the LEDs. However, in U.S. Pat. No. 6,410,942 the growth substrate remains as part of the micro-LED structure and is not removed. The growth substrate adds to the thickness of the LED die and can reduce the overall light extraction efficiency of the array. Even if light is efficiently extracted from one micro-LED, it can enter the growth substrate, undergo total internal reflection from the opposing surface of the growth substrate, and be reflected back into adjacent micro-LEDs where it may be absorbed. U.S. Pat. No. 6,410,942 does not disclose how the absorption coefficient of the semiconductor layers affects the light extraction efficiency of the LED die or the reflectivity of the LED die to externally incident light.

Increasing the density of light extracting elements by decreasing the size of micro-LEDs illustrated in U.S. Pat. No. 6,410,942 may increase the light extraction efficiency of a single micro-LED, but can also decrease the reflectivity of the micro-LED to incident light. The same structures that extract light from the LED die also cause light that is externally incident onto the die to be injected into the high-loss semiconductor layers and to be transported for relatively long distances within the layers. This effect is described in greater detail in U.S. patent application Ser. No. 10/952,112, which was previously cited. Light that travels for long distances within the semiconductor layers is strongly absorbed and only a small portion may escape from the die as reflected light. In one embodiment of U.S. Pat. No. 6,410,942, the micro-LEDs are circular with a diameter of 1 to 50 microns. In another embodiment, the micro-LEDs are formed by etching holes through the semiconductor layers resulting in micro-LEDs with a preferred width between 1 and 30 microns. Micro-LEDs with such a high density of light extracting elements can have reduced reflectivity for externally incident light.

In comparison to surfaces that have a high density of light extracting elements, smooth LED surfaces that do not have light extracting elements have poor light extraction efficiency. However, the resulting LEDs can be good light reflectors. This effect is also described in U.S. patent application Ser. No. 10/952,112. Light that is incident on the LED die surface will be refracted to smaller angles (less than the critical angle in Equation 1) inside the LED die, will travel directly across the thin semiconductor layers, will be reflected by a back mirror surface, will travel directly across the semiconductor layers a second time and then exit the LED die surface as reflected light. In such cases, the incident light is not trapped in the semiconductor layers by total internal reflection and does not necessarily undergo excessive absorption.

U.S. Pat. No. 6,495,862 discloses forming an embossed surface on the LED to improve light extraction. The surface features can include cylindrical or spherical lens-shaped convex structures. However, U.S. Pat. No. 6,495,862 does not disclose how the absorption coefficient of the semiconductor layers affects the light extraction efficiency of the LED die or the reflectivity of the LED die to externally incident light.

T. Fujii et al in Applied Physics Letters (volume 84, number 6, pages 855-857, 2004) disclose forming hexagonal cone-like structures on the LED surface to improve light extraction. A two-fold to three-fold increase in light extraction efficiency was obtained by this method. In this paper, T. Fujii does not disclose how the absorption coefficient of the semiconductor layers affects the light extraction efficiency or the reflectivity of the LED die.

Many commercially available LEDs, including the GaN-based LEDs made from GaN, InGaN, AlGaN and AlInGaN, have relatively low reflectivity to externally incident light. One reason for the low reflectivity is the semiconductor layers have relatively high optical absorption at the emitting wavelength of the internally generated light. Due to problems fabricating thin layers of the semiconductor materials, an absorption coefficient greater than 50 cm⁻¹ is typical.

Another reason for the low reflectivity of many present LED designs is the LED die may include a substrate that absorbs a significant amount of light. For example, GaN-based LEDs with a silicon carbide substrate are usually poor light reflectors with an overall reflectivity of less than 50%.

An additional reason for the low reflectivity of many present LED designs is external structures on the LEDs, including the top metal electrodes, metal wire bonds and sub-mounts to which the LEDs are attached, that are not designed for high reflectivity. For example, the top metal electrodes and wire bonds on many LEDs contain materials such as gold that have relatively poor reflectivity. Reflectivity numbers on the order of 35% in the blue region of the optical spectrum are common for gold electrodes.

Present LED designs usually have either relatively low optical reflectivity (less than 50%, for example) or have high reflectivity combined with low light extraction efficiency (for example, less than 25%). For many applications, including illumination systems utilizing light recycling, it would be desirable to have LEDs that exhibit both high reflectivity to incident light and high light extraction efficiency. It would also be desirable to develop LEDs that do not require a large transparent optical element such as a hemispherical lens or side-emitting lens in order to achieve high light extraction efficiency. LEDs that do not have such lens elements are thinner and take up less area than traditional LEDs. Such ultra-thin LEDs having high light extraction efficiency and high reflectivity can be used, for example, in applications such as LCD backlights that require a low-profile illumination source.

### SUMMARY OF THE INVENTION

One embodiment of this invention is a light emitting diode that emits internally generated light in an emitting wavelength range and reflects externally incident light with a reflectivity greater than 60 percent in the emitting wavelength range. The light emitting diode includes a first reflecting electrode, a multi-layer semiconductor structure and a second reflecting electrode. The first reflecting electrode reflects both the internally generated light and the externally incident light. The first reflecting electrode can be a reflecting metal layer, a transparent layer and a reflecting metal layer, or a transparent layer and a reflecting metal layer with a plurality of metal contacts extending through the transparent layer. The multi-layer semiconductor structure has an absorption coefficient less than 50 cm⁻¹ in the emitting wavelength range and includes a first doped semiconductor layer underlying the first reflecting electrode, an active region that underlies the first doped semiconductor layer and that emits the internally generated light, a second doped semiconductor layer underlying the active region and, optionally, a current spreading layer. The active region can be, for example, a p-n homojunction, a p-n heterojunction, a single quantum well or a multiple quantum well. A second reflecting electrode underlies the multi-layer semiconductor structure and reflects both the internally generated light and the externally incident light. The second reflecting electrode can be a first transparent layer and a reflecting metal layer; or a second transparent layer, a first transparent layer and a reflecting metal layer; or a second transparent layer, a first transparent layer and a reflecting metal layer with a plurality of metal contacts extending from the reflecting metal layer through the first transparent layer to the second transparent layer. An array of light extracting elements extends at least part way through the multi-layer semiconductor structure and improves the extraction efficiency for the internally generated light. The light extracting elements can have angled sidewalls and can be arrays of pyramids, lenses, trenches, holes, ridges, grooves or cones. The light extracting elements can also be sub-micron sized holes or grooves that form a photonic crystal. In a preferred embodiment of this invention, the light extraction efficiency of the LED is greater than 40 percent.

### BRIEF DESCRIPTION OF THE DRAWINGS

A more detailed understanding of the present invention, as well as other objects and advantages thereof not enumerated herein, will become apparent upon consideration of the following detailed description and accompanying drawings, wherein:

FIGS. 1A-1E are side cross-sectional views of embodiments of the light emitting diode of this invention that exhibit high reflectivity to externally incident light and improved extraction efficiency for internally generated light. FIG. 1A is a light emitting diode with reflecting electrodes on opposite sides of a multi-layer semiconductor structure. FIG. 1B is a side cross-sectional view of a light emitting diode with reflecting electrodes on the same side of a multi-layer semiconductor structure. FIG. 1C is a side cross-sectional view of a light emitting diode having a bottom reflecting electrode with two layers. FIG. 1D is a side cross-sectional view of a light emitting diode having a bottom reflecting electrode with three layers. FIG. 1E is a side cross-sectional view of a light emitting diode having a bottom reflecting electrode with three layers and having electrical contacts through the middle layer.

FIG. 2A is a side cross-sectional side view of a light emitting diode that has a top reflecting electrode with two layers. FIG. 2B is a side cross-sectional view of a light emitting diode that has a top reflecting electrode with two layers and electrical contacts that extend from the topmost layer of the top reflecting electrode through the second layer.

FIG. 3A is a plan view of an embodiment of the light emitting diode of this invention that exhibits high reflectivity to externally incident light, that exhibits high extraction efficiency for internally generated light and that incorporates an array of square pyramids. FIG. 3B is a side cross-sectional view of the embodiment along the I-I plane illustrated in FIG. 3A.

FIGS. 3C-3D are side cross-sectional views of the light emitting diode of FIG. 3A illustrating example light rays.

FIG. 4A is a plan view of an embodiment of the light emitting diode of this invention that exhibits high reflectivity to externally incident light, that exhibits high extraction efficiency for internally generated light and that incorporates an array of lenses. FIG. 4B is a side cross-sectional view of the embodiment along the I-I plane illustrated in FIG. 4A.

FIG. 5A is a graph of the light extracting efficiency of an LED that incorporates an array of pyramids. FIG. 5B is a graph of the LED reflectivity.

FIG. 6 is a graph of LED reflectivity versus light extracting efficiency for light emitting diodes.

### DETAILED DESCRIPTION OF THE PREFERRED EMBODIMENTS

The preferred embodiments of the present invention will be better understood by those skilled in the art by reference to the above listed figures. The preferred embodiments of this invention illustrated in the figures are not intended to be exhaustive or to limit the invention to the precise form disclosed. The figures are chosen to describe or to best explain the principles of the invention and its applicable and practical use to thereby enable others skilled in the art to best utilize the invention. The above listed figures are not drawn to scale. In particular, the thickness dimension of the LEDs is expanded to better illustrate the various layers of the devices.

Inorganic light-emitting diodes can be fabricated from GaN-based semiconductor materials containing gallium nitride (GaN), aluminum gallium nitride (AlGaN), indium gallium nitride (InGaN) and aluminum indium gallium nitride (AlInGaN). Other appropriate LED materials include, for example, aluminum nitride (AlN), boron nitride (BN), indium nitride (InN), aluminum gallium indium phosphide (AlGaInP), gallium arsenide (GaAs), indium gallium arsenide (InGaAs), indium gallium arsenide phosphide (InGaAsP), diamond or zinc oxide (ZnO), for example, but are not limited to such materials. Especially important LEDs for this invention are GaN-based LEDs that emit light in the ultraviolet, blue, cyan and green region of the optical spectrum and AlGaInP LEDs that emit light in the yellow and red regions of the optical spectrum.

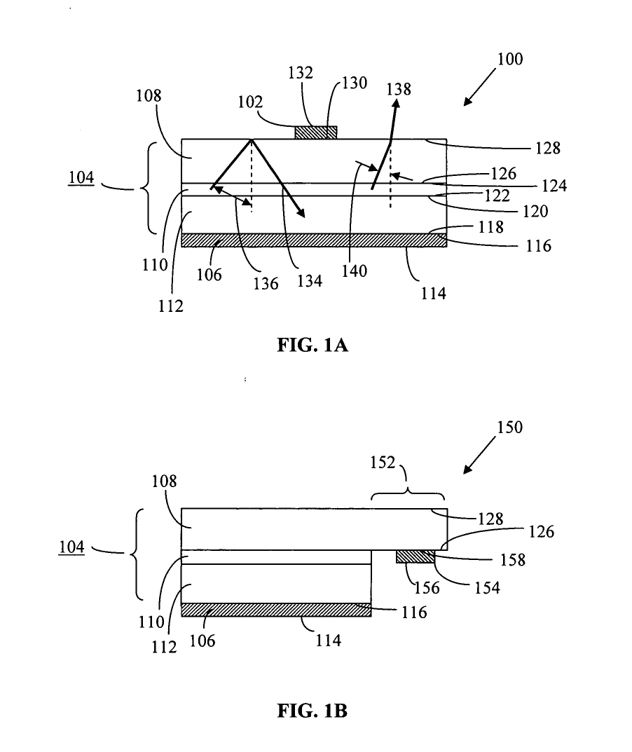

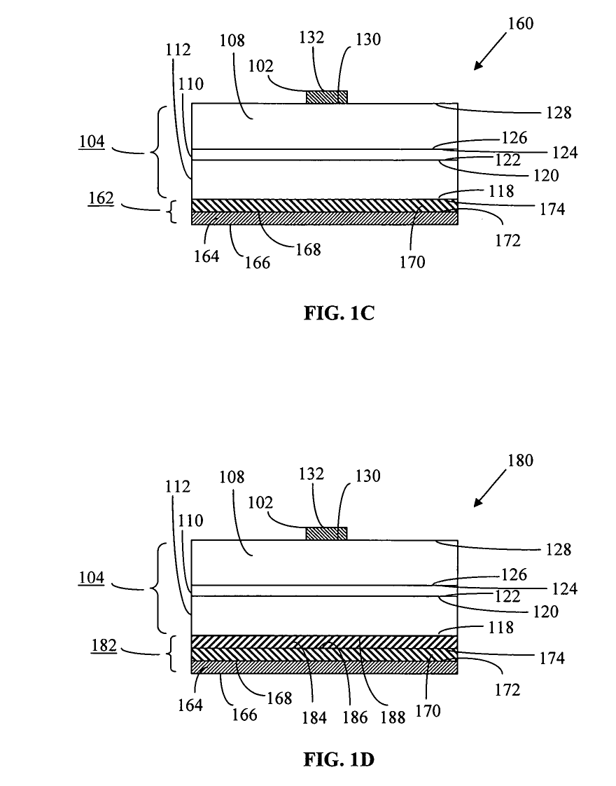

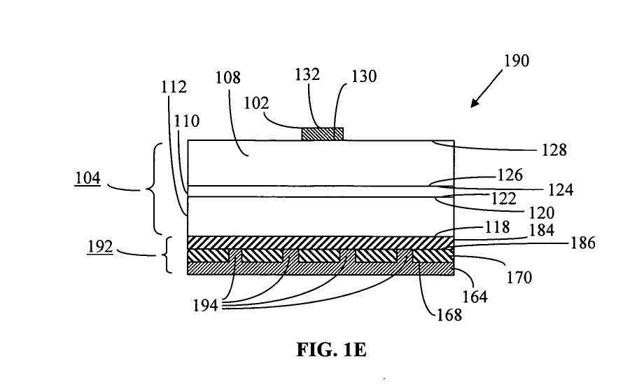

Five embodiments of this invention are illustrated in FIGS. 1A-1E. FIG. 1A is a side cross sectional view of a first embodiment of a light emitting diode (LED) 100 that exhibits high reflectivity to externally incident light and improved extraction efficiency for internally generated light.

LED 100 includes a first reflecting electrode 102, a multi-layer semiconductor structure 104 and a second reflecting electrode 106, which is on the opposite side of the multi-layer semiconductor structure 104 from the first reflecting electrode 102. The multi-layer semiconductor structure 104 includes a first doped semiconductor layer 108, an active region 110 and a second doped semiconductor layer 112, which is on the opposite side of the active region 110 from the first doped semiconductor layer 108.

The first electrode 102 and the second electrode 106 may be fabricated from reflecting metals. For example, the first reflecting electrode 102 and the second reflecting electrode 106 may be formed from one or more metals or metal alloys containing, but not limited to, silver, aluminum, nickel, titanium, chromium, platinum, palladium, rhodium, rhenium, ruthenium and tungsten. Preferred metals are aluminum and silver.

The multi-layer semiconductor structure 104 of the LED 100 can be fabricated from GaN-based semiconductor materials containing gallium nitride (GaN), aluminum gallium nitride (AlGaN), indium gallium nitride (InGaN) and aluminum indium gallium nitride (AlInGaN). Other appropriate LED materials include, for example, aluminum nitride (AlN), boron nitride (BN), indium nitride (InN), aluminum gallium indium phosphide (AlGaInP), gallium arsenide (GaAs), indium gallium arsenide (InGaAs), indium gallium arsenide phosphide (InGaAsP), diamond or zinc oxide (ZnO), for example, but are not limited to such materials. Relevant LEDs for this invention are GaN-based LEDs that emit light in the ultraviolet, blue, cyan and green region of the optical spectrum and AlGaInP LEDs that emit light in the yellow and red regions of the optical spectrum.

The active region 110 of the multi-layer semiconductor structure 104 is a p-n homojunction, a p-n heterojunction, a single quantum well or a multiple quantum well of the appropriate semiconductor material for the LED 100.

LED 100 is assumed for purposes of illustration to be a flip-chip, GaN-based LED. It should be noted, however, that LED 100 may be fabricated from any suitable light-emitting semiconductor material such as the materials listed above and that a flip-chip structure is not required. To briefly summarize the important fabrication steps for this flip-chip, GaN-based, illustrative example, first a multi-layer semiconductor structure 104 is fabricated on a growth substrate (not shown). A second reflecting electrode 106 is deposited onto the multi-layer semiconductor structure opposite the growth substrate, followed by the attachment of a sub-mount (not shown) to the second reflecting electrode. The structure is inverted (flipped) and a liftoff process removes the growth substrate, exposing the surface 128 of the multi-layer semiconductor structure that was originally attached to the growth substrate. Finally, a first reflecting electrode 102 is deposited and patterned on the exposed surface 128 of the multi-layer semiconductor structure 104 opposite the second reflecting electrode 106.

The details of the structure and fabrication of the illustrative example LED 100 will now be described.

The first doped semiconductor layer 108 is an n-doped GaN layer, which is epitaxially deposited or otherwise conventionally fabricated on a growth substrate (not shown). The n-doped GaN semiconductor layer has a first or upper surface 128 and a second or lower surface 126, opposite the first surface 128.

The active region 110 is a GaN-based p-n heterojunction, which is epitaxially deposited or otherwise conventionally fabricated on the first doped semiconductor layer 108. The GaN-based p-n heterojunction active region 110 has a first or upper surface 124, deposited or fabricated on the second surface 126 of the first doped semiconductor layer 108, and a second or lower surface 122, opposite the first surface 124.

The second doped semiconductor layer 112 is a p-doped GaN layer, which is epitaxially deposited or otherwise conventionally fabricated on the active region 110. The p-doped GaN semiconductor layer has a first or upper surface 120, epitaxially deposited or otherwise fabricated on the second surface 122 of the active region 110, and a second or lower surface 118, opposite the first surface 120.

The second reflecting electrode 106 of LED 100 is silver and has a first, upper and inner surface 116 and a second, lower or outer surface 114, opposite the first surface 116.

The first reflecting electrode 102 is aluminum, which is deposited or otherwise conventionally fabricated on the first doped semiconductor layer 108. The first reflecting electrode 102 has a first, inner or lower surface 130, deposited or fabricated on the first surface 128 of the first doped semiconductor layer 108, and a second, outer or upper surface 132, opposite the first surface 130.

The inner surface 130 of the first reflecting electrode 102 is an inner reflecting surface for the multi-layer semiconductor structure 104 of the LED 100. The outer surface 132 of the first reflecting electrode 102 is an outer reflecting surface for externally incident light directed to LED 100.

The first reflecting electrode 102 only partially covers the surface 128 of the first doped semiconductor layer 108. Portions of the surface 128 of the first doped semiconductor layer 108, not covered by the first reflecting electrode 102, are exposed and those exposed portions of the surface 128 of the first doped semiconductor layer 108 are an output or exit surface for the light emitted by the LED 100.

The light emitting diode 100 has a first reflecting electrode 102, a multi-layer semiconductor structure 104 having a first doped semiconductor layer 108, an active region 110 and a second doped semiconductor layer 112, and a second reflecting electrode 106.

The active region 110 emits internally generated light in an emitting wavelength range when a voltage is applied across the first reflecting electrode 102 and the second reflecting electrode 106. The emitting wavelength range can include any optical wavelength. For an LED having a p-n heterojunction active region 110, the emitting wavelength range typically has a full width of approximately 50 nm at the half-maximum points of the wavelength range. For visual and display applications, preferably the emitting wavelength range is between about 400 nm and about 700 nm.

The total thickness of the multi-layer semiconductor structure 104 is usually on the order of a few microns. For example, the total thickness of the multi-layer semiconductor structure 104 can be three to five microns. If the total thickness of the multi-layer semiconductor structure is greater than five microns, the transmission of light through the structure will be reduced (see equation 2) if the absorption coefficient of the multi-layer semiconductor structure is not correspondingly decreased. If the transmission of light through the multi-layer semiconductor structure is reduced, the extraction efficiency and the reflectivity of LED 100 will also be reduced.

The multi-layer semiconductor structure 104 absorbs light and has an absorption coefficient that depends on wavelength. In many cases, the absorption coefficient is not uniform across the different semiconductor layers of the multi-layer semiconductor structure. If the different semiconductor layers that make up the multi-layer semiconductor structure 104 have different absorption coefficients, the absorption coefficient for the multi-layer semiconductor structure is defined in this specification as the thickness-weighted average absorption coefficient. The weighting function is the fractional thickness of each semiconductor layer in the multi-layer semiconductor structure 104. For example, if 100% of the thickness of the multi-layer semiconductor structure 104 has a uniform absorption coefficient of 50 cm⁻¹ in the emitting wavelength range, then the thickness-weighted average absorption coefficient is 50 cm⁻¹. If 50% of the thickness of the multi-layer semiconductor structure 104 has an absorption coefficient of 25 cm⁻¹ and 50% of the thickness of the multi-layer semiconductor structure 104 has an absorption coefficient of 75 cm⁻¹, then the thickness-weighted average absorption coefficient is also 50 cm⁻¹.

Both the light extraction efficiency of LED 100 and the reflectivity of LED 100 to externally incident light depend on several factors. These factors include the absorption coefficient of the multi-layer semiconductor structure, the reflectivity of the first reflecting electrode 102 and the reflectivity of the second reflecting electrode 106. By lowering the absorption coefficient of the multi-layer semiconductor structure, the light extraction efficiency of LED 100 and the reflectivity of LED 100 to externally incident light will increase. Furthermore, increasing the reflectivity of the first reflecting electrode and/or the second reflecting electrode will increase the light extraction efficiency of LED 100 and the reflectivity of LED 100 to externally incident light.

In order to improve the light extraction efficiency of LED 100 and to improve the reflectivity of LED 100 to externally incident light, preferably the absorption coefficient (i.e. the thickness-weighted average absorption coefficient) of the multi-layer semiconductor structure 104 in the emitting wavelength range of the internally generated light is less than 50 cm⁻¹. More preferably, the absorption coefficient of the multi-layer semiconductor structure in the emitting wavelength range is less than 25 cm⁻¹. Most preferably, the absorption coefficient of the multi-layer semiconductor structure in the emitting wavelength range is less than 10 cm⁻¹. In prior art GaN-based LEDs, the absorption coefficient of the multi-layer semiconductor structure in the emitting wavelength range of the internally generated light is generally greater than 50 cm⁻¹. In order to minimize the absorption coefficient of the multi-layer semiconductor structure, the absorption coefficient of each semiconductor layer of the multi-layer semiconductor structure must be minimized. This can be accomplished by improving the deposition processes for the different semiconductor layers in order to reduce impurities or defects and to improve the crystalline structure of the layers. For example, hydride vapor phase epitaxy (HVPE) can be used to epitaxially grow the first doped semiconductor layer or the entire multi-layer semiconductor structure. HVPE does not have the carbon impurities that can be present in the metal-organic chemical vapor deposition (MOCVD) processes normally used in GaN LED fabrication. Alternatively, if MOCVD is used to deposit the semiconductor layers, a higher deposition temperature can be used to reduce carbon impurities and crystalline defects in the layers. If the active region 110 of LED 100 is a p-n heterojunction, preferably the entire multi-layer semiconductor structure is fabricated by HVPE.

A common electrode material for the outer surface 132 of the first reflecting electrode in prior art light emitting devices is gold. Gold has very good electrical properties, but is a poor optical reflector for visible light in the range of 400 nm to 550 nm. For LEDs that emit light in the 400-550 nm range or thereabouts, it is advantageous to replace gold with a more reflective material. In order to improve the light extraction efficiency of LED 100 and to improve the reflectivity of LED 100 to externally incident light, preferably the first reflecting electrode 102 has a reflectivity greater than 60 percent in the emitting wavelength range. More preferably, the first reflecting electrode 102 has a reflectivity greater than 80 percent in the emitting wavelength range. Suitable materials for the first reflecting electrode that have a reflectivity greater than 80 percent include aluminum and silver. In the illustrative example for LED 100, the first reflecting electrode is fabricated from aluminum.

The second reflecting electrode 106 covers a larger surface area than the first reflecting electrode 102. Consequently, the reflectivity of the second reflecting electrode is more critical than the reflectivity of the first metal electrode. In order to improve the light extraction efficiency of LED 100 and to improve the reflectivity of LED 100 to externally incident light, preferably the reflectivity of the second reflecting electrode 106 is greater than 85 percent in the emitting wavelength range. More preferably the reflectivity of the second reflecting electrode is greater than 90 percent in the emitting wavelength range. Most preferably, the reflectivity of the second reflecting electrode is greater than 95 percent in the emitting wavelength range. A suitable material for the second reflecting electrode that has a reflectivity greater than 95 percent is silver. In the illustrative example for LED 100, the second reflecting electrode is fabricated from silver.

The outer surface 128 of the first doped semiconductor layer 108 of the multi-layer semiconductor structure 104 is the exit or output surface for light emitted by the active region 110. The first reflecting electrode 102 only covers a small portion of the outer surface 128. The reflective inner surface 116 of the second reflecting electrode 106 preferably covers the entire surface 118 of the multi-layer semiconductor structure 104 and is a reflective surface for light emitted by the active region 110.

Example light rays 134 and 138 illustrate internally generated light that is emitted by the active region 110. Internally generated light ray 134 is emitted by active region 110 toward output surface of LED 100. Internally generated light ray 134 is directed at an angle 136 that is greater than the critical angle for output surface 128. Internally generated light ray 134 is reflected by total internal reflection and is redirected toward internal reflective surface 116 of the second reflecting electrode 106.

Internally generated light ray 138 is emitted by active region 110 toward outer surface 128 of the first semiconductor layer 108 of LED 100. Internally generated light ray 138 is directed at an angle 140 that is less than the critical angle for outer surface 128. Internally generated light ray 138 is transmitted through outer surface 128.

If the first doped semiconductor layer 108 is an n-doped layer, then the second doped semiconductor layer 112 is a p-doped layer. However, the two layers can be reversed. If the first doped semiconductor layer 108 is a p-doped layer, then the second doped semiconductor layer 112 is an n-doped layer. The two doped semiconductor layers 108 and 112 will have opposite n and p conductivity types.

It is well known by those skilled in the art that the multi-layer semiconductor structure 104 may include additional layers in order to adjust and improve the operation of the LED 100. For example, a current spreading layer may be inserted between surface 130 of the first reflecting electrode 102 and surface 128 the first doped semiconductor layer 108. Such a current spreading layer will have the same conductivity type as the first doped semiconductor layer and will improve the uniformity of current injection across the entire active region. In addition, a current spreading layer may be inserted between surface 118 of the second doped semiconductor layer and surface 116 of the second reflecting electrode 106. The latter current spreading layer will have the same conductivity type as the second doped semiconductor layer. As another example, an electron blocking layer may inserted either between surface 126 of the first doped semiconductor layer 108 and surface 124 of the active region 110 or between surface 122 of the active region 110 and surface 120 of the second doped semiconductor layer. The electron blocking layer reduces the escape of electrons from the active region. If the current spreading layers or the electron blocking layers absorb part of the light passing through the layers, both the extraction efficiency of LED 100 and the reflectivity of LED 100 to externally incident light will be reduced. In order to minimize these effects, the absorption coefficients and thicknesses of any current spreading layers and/or electron blocking layers are preferably minimized.

FIG. 1B is a cross sectional view of another embodiment of this invention, LED 150, that exhibits high reflectivity to externally incident light and improved extraction efficiency for internally generated light. LED 150 is equivalent to LED 100 except that LED 150 is constructed in a flip-chip configuration with both the first reflecting electrode 154 and the second reflecting electrode 106 located on the same side of the LED 150. In this embodiment, the first doped semiconductor layer 108 has a larger surface area than the active region 110 and the second doped semiconductor layer 112. A portion 152 of the first doped semiconductor layer 108 will extend away from the active region 110 and the second doped semiconductor layer 112 exposing a portion 152 of the second surface 126 of the first doped semiconductor layer 108. The first reflecting electrode 154 is located on the exposed second or inner surface 126 of the first doped semiconductor layer 108 adjacent to the action region 110 instead of the first or outer surface 128 of the first doped semiconductor layer 108. The first reflecting electrode 154 has a first or upper surface 158 and a second or lower exposed surface 156, opposite the first surface 158. The first surface 158 of the first reflecting electrode 154 is deposited or fabricated on the exposed second surface 126 of the first doped semiconductor layer 108.

However, the first reflecting electrode 154 is in electrical contact with the first doped semiconductor layer 108. The first doped semiconductor layer 108 functions as a current spreading layer that directs electrical current from the first reflecting electrode 154 to the active region 110.

The first surface 128 of the first doped semiconductor layer 108 has no reflecting electrode on its surface. Light emitted by the active region 110 can exit across the entire area of the first surface 128 of the first doped semiconductor layer 108. The entire surface functions as an output surface. The first reflecting electrode 154, now on the lower side of LED 150, can reflect both internally generated light and externally incident light.

FIG. 1C is a side cross sectional view of another embodiment of this invention, LED 160, that exhibits high reflectivity to externally incident light and improved extraction efficiency for internally generated light. LED 160 is similar to LED 100 except that LED 160 has a second reflecting electrode 162 that includes two layers, a first transparent layer 170 and a reflecting metal layer 164. Having a two-layer second reflecting electrode 162 in LED 160 increases the reflectivity of the second reflecting electrode of LED 160 compared to the single-layer second reflecting 106 of LED 100. Increasing the reflectivity of the second reflecting electrode increases the light extraction of LED 160 and the overall reflectivity of LED 160 to externally incident light.

First transparent layer 170 of the second reflecting electrode 162 has a first or upper surface 174 and a second or lower surface 172, opposite the first surface 174. The first surface 174 of the first transparent layer 170 is deposited or fabricated on the second surface 118 of the second doped semiconductor layer 112. Preferably the refractive index of the first transparent layer 170 is less than the refractive index of the second doped semiconductor layer 112. The preferred refractive index of the first transparent layer 170 is between 1.05 and 2.3. More preferably, the refractive index of the first transparent layer 170 is between 1.10 and 1.60.

The thickness of the first transparent layer 170 can be one-quarter wave or thicker than one-quarter wave. A thickness of one wave is defined as the wavelength in air of the light emitted by the LED divided by the refractive index of the first transparent layer 170. The preferred thickness of the first transparent layer 170 is one-quarter wave or three-quarter wave. The thickness and low refractive index of the first transparent layer 170 coupled with the reflecting metal layer 164 cause nearly all of the light emitted downward by the active region 110 to be reflected rather than absorbed, enhancing light extraction efficiency and the overall reflectivity of LED 160.

The first transparent layer 170 can be fabricated, for example, from dielectric materials such as silicon dioxide (SiO₂), silicon nitride (Si₃N₄), magnesium fluoride (MgF₂) or from electrically conducting materials such as transparent conductive oxides. Transparent conductive oxides include, but are not limited to, indium tin oxide, ruthenium oxide, copper-doped indium oxide and aluminum-doped zinc oxide. The dielectric material or the transparent conductive oxide can be a solid material or a porous material. If the material is porous, the pores are filled with a vacuum, air or an inert gas such as nitrogen or argon. A porous material has a lower refractive index than a solid material, resulting in higher reflectivity for the second reflecting electrode 162. Preferably the first transparent layer 170 in LED 160 is electrically conductive.

The reflecting metal layer 164 of the second reflecting electrode 162 has a first or upper surface 168 and a second or lower surface 166, opposite the first surface 168. The first surface 168 is deposited or fabricated on the first surface 172 of the first transparent layer 170. The reflecting metal layer 164 of the second reflecting electrode 162 can be fabricated from one or more metals or metal alloys containing, but not limited to, silver, aluminum, nickel, titanium, chromium, platinum, palladium, rhodium, rhenium, ruthenium and tungsten. Preferred metals are aluminum and silver.

FIG. 1D is a side cross sectional view of another embodiment of this invention, LED 180, that exhibits high reflectivity to externally incident light and improved extraction efficiency for internally generated light. LED 180 is similar to LED 100 and LED 160 except that LED 180 has a second reflecting electrode 182 that includes three layers, second transparent layer 184, a first transparent layer 170 and a reflecting metal layer 164. The purpose of the second transparent layer 184 is to lower the contact resistance between the second reflecting electrode 182 and the second doped semiconductor layer 112 or to improve current spreading between the second reflecting electrode 182 and the second doped semiconductor layer 112.

The second transparent layer 184 of the second reflecting electrode 182 has a first or upper surface 188 and a second or lower surface 186, opposite the first surface 188. The first surface 188 is deposited or fabricated on the first surface 118 of the second doped semiconductor layer 112. The thickness of the second transparent layer preferably is less than one-quarter wave.

The second transparent layer 184 is an electrically conductive layer. Preferably the second transparent layer 184 is fabricated from a transparent conductive oxide. Transparent conductive oxides include, but are not limited to, indium tin oxide, ruthenium oxide, copper-doped indium oxide or aluminum-doped zinc oxide.

First transparent layer 170 of the second reflecting electrode 182 has a first or upper surface 174 and a second or lower surface 172, opposite the first surface 174. The first surface 174 of the first transparent layer 170 is deposited or fabricated on the second surface 186 of the second transparent layer 184. Preferably the refractive index of the first transparent layer 170 is less than the refractive index of the second doped semiconductor layer 112. The preferred refractive index of the first transparent layer 170 is between 1.05 and 2.3. More preferably, the refractive index of the first transparent layer 170 is between 1.10 and 1.60.

The thickness of the first transparent layer 170 of LED 180 can be one-quarter wave or thicker than one-quarter wave. The preferred thickness of the first transparent layer 170 of LED 180 is one-quarter wave or three-quarter wave. Example dielectric materials and transparent conductive oxide materials for the first transparent layer 170 are listed above. The dielectric material or the transparent conductive oxide can be a solid material or a porous material. If the material is porous, the pores are filled with a vacuum, air or an inert gas such as nitrogen or argon. A porous material has a lower refractive index than a solid material, resulting in higher reflectivity for the second reflecting electrode 182. Preferably the first transparent layer 170 in LED 180 is electrically conductive.

The reflecting metal layer 164 of the second reflecting electrode 162 has a first or upper surface 168 and a second or lower surface 166, opposite the first surface 168. The first surface 168 is deposited or fabricated on the second surface 172 of the first transparent layer 170. Example materials for the reflecting metal layer 164 are listed above.

FIG. 1E is a side cross sectional view of another embodiment of this invention, LED 190, that exhibits high reflectivity to externally incident light and improved extraction efficiency for internally generated light. LED 190 is similar to LED 180 except that LED 190 has a second reflective electrode 192 that includes a plurality of metal contacts 194 that extend from surface 168 of reflecting metal layer 164 and through the first transparent layer 170 to surface 186 of the second transparent layer 184. The purpose of the plurality of metal contacts 194 is to improve the electrical conductivity of the second reflecting electrode 192. Improving the conductivity of the second reflecting electrode is necessary if the first transparent layer 170 is a dielectric material or is a transparent conductive oxide with relatively low electrical conductivity.

The plurality of metal contacts 194 may be fabricated from the same metals as reflecting metal layer 164. To form the plurality of metal contacts, first a plurality of holes is etched through the first transparent layer 170. The holes can be etched by, for example, wet chemical etching, reactive ion etching, plasma etching, ion milling, laser ablation or any other conventional etching process. Metal is deposited in the holes during the fabrication step for the reflecting metal layer 164. The plurality of metal contacts 194 extends in a patterned array across the entire first transparent layer 170. The patterned array of metal contacts 194 may be a regular pattern or an irregular pattern. The pattern of metal contacts may be a uniform pattern or a non-uniform pattern. A non-uniform pattern may be useful to enhance current spreading to regions of the multilayer semiconductor structure 104 that are laterally distant from the first reflecting electrode 102. In such a non-uniform pattern, the density of metal contacts will increase as the lateral distance from the first reflecting electrode 102 increases. The plurality of metal contacts 194 comprise a small fraction of the area between the reflecting metal layer 164 and the second transparent layer 184. For example, the plurality of metal contacts comprise between 0.25 percent and 10 percent of the interface area.

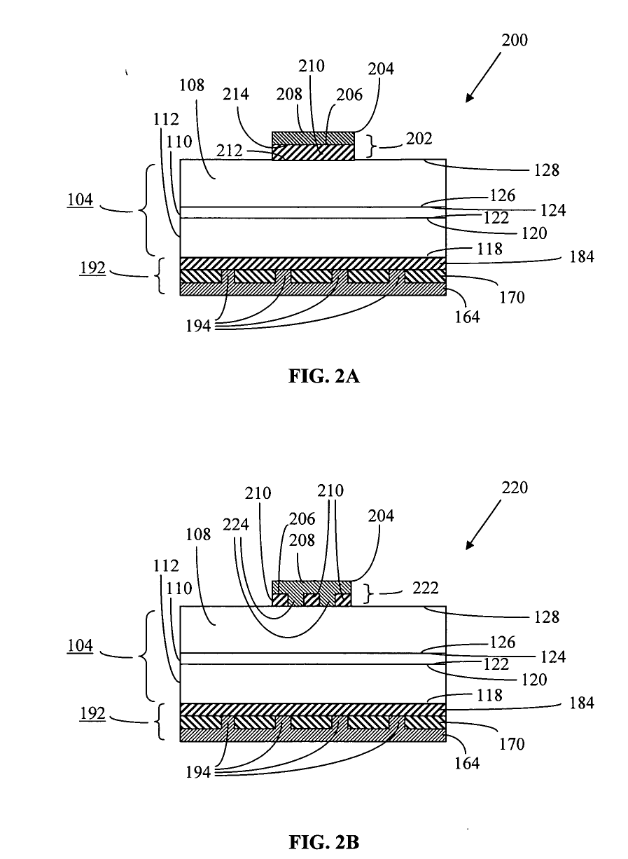

Another embodiment of this invention that exhibits high reflectivity to externally incident light and improved extraction efficiency for internally generated light is LED 200. A side cross-sectional view of LED 200 is shown in FIG. 2A. LED 200 is similar to LED 190 except that the first reflecting electrode 202 of LED 200 includes two layers, a transparent layer 210 and a reflecting metal layer 204. Having a two-layer first reflecting electrode 202 increases the reflectivity of the first reflecting electrode of LED 200 to internally generated light compared to the single-layer first reflecting 102 of LED 100. Increasing the reflectivity of the first reflecting electrode increases the light extraction of LED 200.

Although LED 200 is illustrated with a three-layer second reflecting electrode 192, it is also within the scope of this invention that the second reflecting electrode 192 can have one layer as in LED 100 or two layers as in LED 160.

The transparent layer 210 of the first reflecting electrode 202 has a first or lower surface 212 and a second or upper surface 214, opposite the first surface 212. The first surface 212 of the transparent layer 210 is deposited or fabricated on the first surface 128 of the first doped semiconductor layer 108. Preferably the refractive index of the transparent layer 210 is less than the refractive index of the first doped semiconductor layer 108. The preferred refractive index of the transparent layer 210 is between 1.05 and 2.3. More preferably, the refractive index of the transparent layer 210 is between 1.10 and 1.60.

The thickness of the transparent layer 210 can be one-quarter wave or thicker than one-quarter wave. The preferred thickness of the transparent layer 210 is one-quarter wave or three-quarter wave. The thickness and low refractive index of the transparent layer 210 coupled with the reflecting metal layer 204 cause nearly all of the light emitted upward by the active region 110 to be reflected rather than absorbed, enhancing the light extraction efficiency of LED 200.

The transparent layer 210 can be fabricated, for example, from dielectric materials such as silicon dioxide (SiO₂), silicon nitride (Si₃N₄), magnesium fluoride (MgF₂) or from electrically conducting materials such as transparent conductive oxides. Transparent conductive oxides include, but are not limited to, indium tin oxide, ruthenium oxide, copper-doped indium oxide and aluminum-doped zinc oxide. The dielectric material or the transparent conductive oxide can be a solid material or a porous material. If the material is porous, the pores are filled with a vacuum, air or an inert gas such as nitrogen or argon. A porous material has a lower refractive index than a solid material, resulting in higher reflectivity for the first reflecting electrode 202. Preferably the transparent layer 210 in LED 200 is electrically conductive.

The reflecting metal layer 204 of the first reflecting electrode 202 has a first or lower surface 206 and a second or upper surface 208, opposite the first surface 206. The first surface 206 is deposited or fabricated on the second surface 214 of the transparent layer 210. The reflecting metal layer 204 of the first reflecting electrode 202 can be fabricated from one or more metals or metal alloys containing, but not limited to, silver, aluminum, nickel, titanium, chromium, platinum, palladium, rhodium, rhenium, ruthenium and tungsten. Preferred metals are aluminum and silver.

Another embodiment of this invention that exhibits high reflectivity to externally incident light and improved extraction efficiency for internally generated light is LED 220. A side cross-sectional view of LED 220 is illustrated in FIG. 2B. LED 220 is similar to LED 200 except that LED 220 has a first reflecting electrode 222 that includes a plurality of metal contacts 224 that extend from surface 206 of the reflecting metal layer 204 to surface 128 of the first doped semiconductor layer 108. The purpose of the plurality of metal contacts 224 is to improve the electrical conductivity of the first reflecting electrode 222. Improving the conductivity of the first reflecting electrode is necessary if the transparent layer 210 is a dielectric material or is a transparent conductive oxide with relatively low electrical conductivity.

The plurality of metal contacts 224 may be fabricated from the same metals as reflecting metal layer 204. To form the plurality of metal contacts, first a plurality of holes is etched through the transparent layer 210. The holes can be etched by, for example, wet chemical etching, reactive ion etching, plasma etching, ion milling, laser ablation or any other conventional etching process. Metal is deposited in the holes during the fabrication step for the reflecting metal layer 204. The plurality of metal contacts 224 extends in a patterned array across the first reflecting electrode 222. The patterned array of metal contacts 224 may be a regular pattern or an irregular pattern. The pattern of metal contacts may be a uniform pattern or a non-uniform pattern. The plurality of metal contacts 224 comprises a small fraction of the area of the first reflecting electrode 222. For example, the plurality of metal contacts comprises between 0.25 percent and 10 percent of the area of the first reflecting electrode 222.

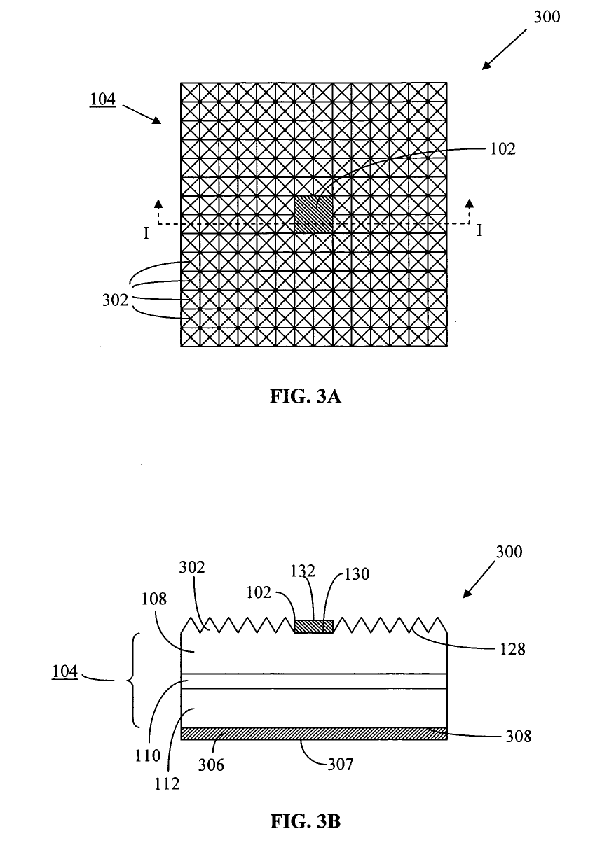

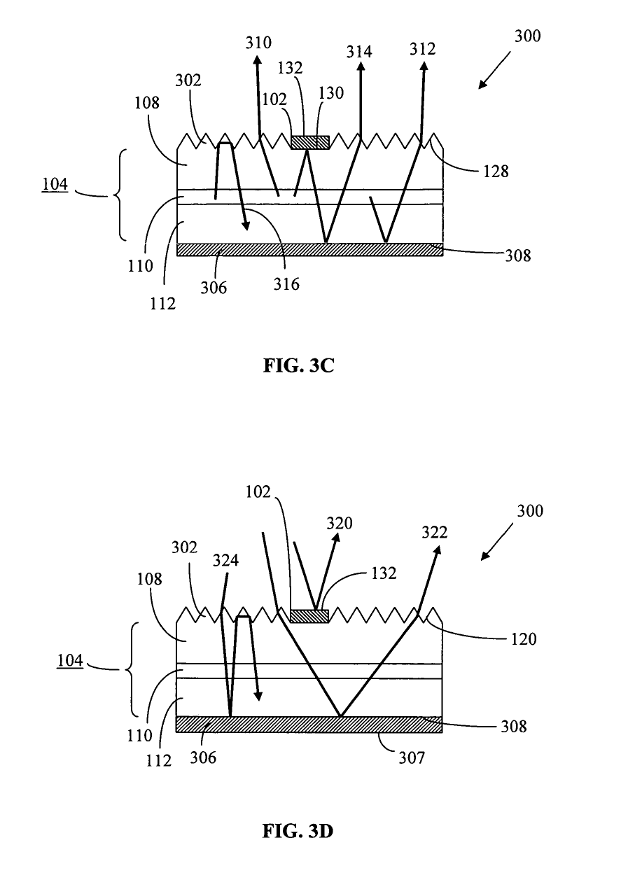

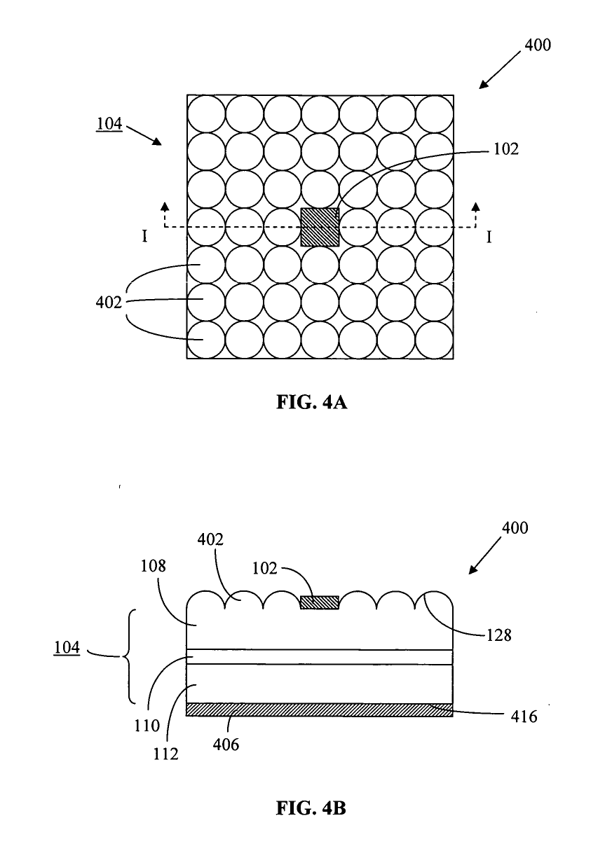

The top exposed surface of an LED may include light extraction elements to increase the amount of light extracted from the LED. Example LEDs with light extracting elements are illustrated in FIGS. 3A-3D and FIGS. 4A-4B. For ease of understanding, the embodiments of this invention illustrated in FIGS. 3A-3D and FIGS. 4A-4B are illustrated with, respectively, single-layer second reflecting electrodes 306 and 406. It is within the scope of this invention that the second reflecting electrodes 306 and 406 can be two-layer or three-layer second reflecting electrodes, such as second reflecting electrodes 162 of FIG. 1C, 182 of FIG. 1D and 192 of FIG. 1E, described and illustrated above.

Another embodiment of this invention is LED 300, illustrated in plan view in FIG. 3A. A side cross-sectional view in the I-I plane of LED 300 indicated in FIG. 3A is illustrated in FIG. 3B. LED 300 is an example of an LED that has high reflectivity to externally incident light and high light extraction efficiency for internally generated light, but does not require a transparent overcoat element such as a hemispherical lens in order to achieve high light extraction efficiency. Since no extra transparent element such as a hemispherical lens is required, LED 300 is a thin, low profile device.

LED 300 includes a first reflecting electrode 102, a multi-layer semiconductor structure 104 and a second reflecting electrode 306. The first reflecting electrode 102 and the multi-layer semiconductor structure 104 have been described previously for LED 100. The second reflecting electrode 306 can be a single metal layer (as illustrated in FIGS. 3B-3D), a two-layer structure that includes a first transparent layer and a metal layer, or a three-layer structure that includes a first transparent layer, a second transparent layer and a metal layer. The first reflecting electrode 102 and the second reflecting electrode 306 reflect both the internally generated light generated by LED 300 and externally incident light.

In addition, LED 300 includes an array of light extracting elements 302 fabricated in the first or output surface 128 of the first doped semiconductor layer 108. The array of light extracting elements extends at least part way through the multi-layer semiconductor structure 104. For example, the array of light extracting elements can extend part way or completely through the first doped semiconductor layer 108. Alternatively, the array of light extracting elements can extend completely through the first doped semiconductor layer 108 and part way or completely though the active region 110. Furthermore, the array of light extracting elements can extend completely through both the first doped semiconductor layer 108 and the active region 110 and part way or completely though the second doped semiconductor layer 112. However, the electrical conductivity of the first doped semiconductor layer 108 must be maintained so that the first doped semiconductor layer 108 can function to spread electrical current from the first reflecting electrode 102 to the entire active region 110. If the exposed surface 128 of the first doped semiconductor layer is covered by the array of light extracting elements 302, then preferably the array of light extracting elements extends only part way through the first doped semiconductor layer 108.

In FIGS. 3A and 3B, the array of light extracting elements 302 is illustrated as an array of square pyramids that each have equal heights. The array of light extracting elements 302 forms a regular pattern and extends part way through the first doped semiconductor layer 108. It is also within the scope of this invention that the array of light extracting elements can be, but is not limited to, an array of hexagonal pyramids, an array of polygonal pyramids, an array of convex lenses, an array of concave lenses, an array of linear ridges, an array of holes, an array of grooves or an array of round cones. The array of light extracting elements may have a regular pattern or an irregular pattern. The array of light extracting elements may also be sub-micron-sized holes or grooves that form a photonic crystal. A photonic crystal can reduce the angular distribution of the light that is extracted from the LED. The pyramids, lenses, ridges, holes, grooves or cones in the array may each have the same size and shape or may each have varying sizes and shapes. The pyramids may have sides with single facets, where the facets are either flat or curved, or sides with multiple facets, either flat or curved.

The array of pyramids can cover all of output surface 128 of the first doped semiconductor layer 108 except for the area of the inner surface 130 of the reflecting electrode 102. Alternately, the array of pyramids can cover only part of the second or output surface 128 of the first doped semiconductor layer 108. Any part of output surface 128 not covered with pyramids can be a planar surface.

A preferred method for making an array of pyramids is a photoelectrochemical etching process utilizing potassium hydroxide and ultraviolet light. Such a process is described by T. Fujii et al in Applied Physics Letters, volume 84, pages 855-857 (2004). An array of hexagonal pyramids is formed by this method. The array has an irregular pattern that contains pyramids of varying sizes and shapes. Other etching processes including, but not limited to, laser ablation, wet chemical etching, plasma etching, reactive ion etching and ion milling may also be used to fabricate light extracting elements such as pyramids in the output surface 128 of the first doped semiconductor layer 106 of the LED 300.

Example light rays in FIGS. 3C and 3D illustrate the extraction and reflection of internally generated light and the reflection of externally incident light.

In FIG. 3C, internally generated light ray 310 is emitted in active region 110 and is directed within the multi-layer semiconductor structure 104 of the LED 300 to the output surface 128 of the first doped semiconductor layer 108. Internally generated light ray 310 is extracted by the array of light extraction elements 302 and exits LED 300.

Internally generated light ray 312 is emitted by active region 110 and is directed within the multi-layer semiconductor structure 104 of the LED 300 to the second reflecting electrode 306. Internally generated light ray 312 is reflected by the inner surface 308 of the second reflecting electrode 306 and is directed to the output surface 128 of the first doped semiconductor layer 108. Internally generated light ray 312 is extracted by the array of light extraction elements 302 and exits LED 300.

Internally generated light ray 314 is emitted by active region 110 and is directed within the multi-layer semiconductor structure 104 of the LED 300 to the first reflecting electrode 102. Internally generated light ray 314 is reflected by the inner surface 130 of the first reflecting electrode 102 and is directed to the second reflecting electrode 306. Internally generated light ray 314 is reflected by the inner surface 308 of the second reflecting electrode 306 and is directed to the output surface 128 of the first doped semiconductor layer 108. Internally generated light ray 314 is extracted by the array of light extraction elements 302 and exits LED 300.

Internally generated light ray 316 is emitted by active region 110 and is directed within the multi-layer semiconductor structure 104 of the LED 300 to the output surface 128 of the first doped semiconductor layer 108. Internally generated light ray 316 undergoes total internal reflection two times at the surface 128 of the array of light extraction elements 302 and is directed toward the second reflecting electrode 306. Internally generated light ray 316 may undergo multiple reflections or multiple total internal reflections (not shown) inside LED 300 and will either exit LED 300 through the light extraction elements 302 or will be absorbed by the multi-layer semiconductor structure 104 or by the first or second reflecting electrodes 102 and 306.

In FIG. 3D, externally incident light ray 320 is directed toward first reflecting electrode 102. Externally incident light ray 320 is reflected by the outer surface 132 of the first reflecting electrode 102 and does not enter LED 300.

Externally incident light ray 322 is directed toward the outer surface 128 of the array of light extraction elements 302. Externally incident light ray 322 is transmitted by the outer surface 128 and is directed through the multi-layer semiconductor structure 104 of the LED 300 toward the second reflecting electrode 306. Externally incident light ray 322 is reflected by the inner surface 308 of the second reflecting electrode 306 and is directed to the output surface 128 of the first doped semiconductor layer 108. Externally incident light ray 322 is extracted by the array of light extraction elements 302 and exits LED 300.

Alternatively, an externally incident light ray that enters the multi-layer semiconductor structure 104 may be absorbed by the multi-layer semiconductor structure or by the first or second reflecting electrodes or the externally incident light ray may undergo multiple reflections or total internal reflections inside LED 300 before either being absorbed or exiting the LED. For example, externally incident light ray 324 is directed toward the outer surface 128 of the array of light extraction elements 302. Externally incident light ray 324 is transmitted by the outer surface 128 and is directed through the multi-layer semiconductor structure 104 of the LED 300 toward the second reflecting electrode 306. Externally incident light ray 324 is reflected by the inner surface 308 of the second reflecting electrode 306 and is directed back to the outer surface 128 of the first doped semiconductor layer 108. Externally incident light ray 324 undergoes total internal reflection two times by surface 128 and is directed back toward the second reflecting electrode 306. Externally incident light ray 324 may undergo additional reflections (not shown) inside LED 300 before either being absorbed or exiting LED 300.

To summarize, a first portion of the internally generated light will exit the LED and a second portion of the internally generated light will be absorbed by either the multi-layer semiconductor structure or by the first or second reflecting electrodes of the LED. A first portion of the externally incident light will be reflected by the LED and a second portion of the externally incident light will be absorbed by either the multi-layer semiconductor structure or by the first or second reflecting electrodes of the LED.

Both the light extraction efficiency of LED 300 and the reflectivity of LED 300 to externally incident light depend on the factors listed previously for LED 100. These factors include the absorption coefficient of the multi-layer semiconductor structure 104 of LED 300, the reflectivity of the first reflecting electrode 102 and the reflectivity of the second reflecting electrode 306. By lowering the absorption coefficient of the multi-layer semiconductor structure, the light extraction efficiency of LED 300 and the reflectivity of LED 300 to externally incident light will increase. Furthermore, increasing the reflectivity of the first reflecting electrode 102 and/or the second reflecting electrode 306 will increase the-light extraction efficiency of LED 300 and the reflectivity of LED 300 to externally incident light.

In order to improve the light extraction efficiency of LED 300 and to improve the reflectivity of LED 300 to externally incident light, preferably the first reflecting electrode has a reflectivity greater than 60 percent in the emitting wavelength range of the internally generated light. More preferably, the first reflecting electrode has a reflectivity greater than 80 percent in the emitting wavelength range.

In addition, in order to improve the light extraction efficiency of LED 300 and to improve the reflectivity of LED 300 to externally incident light, preferably the reflectivity of the second reflecting electrode 306 is greater than 92 percent in the emitting wavelength range of the internally generated light. More preferably the reflectivity of the second reflecting electrode is greater than 96 percent in the emitting wavelength range. Most preferably, the reflectivity of the second reflecting electrode is greater than 98 percent in the emitting wavelength range.

Furthermore, in order to improve the light extraction efficiency of LED 300 and to improve the reflectivity of LED 300 to externally incident light, preferably the absorption coefficient (i.e. the thickness-weighted average absorption coefficient) of the multi-layer semiconductor structure is less than 50 cm⁻¹ in the emitting wavelength range of the internally generated light. More preferably, the absorption coefficient of the multi-layer semiconductor structure is less than 25 cm⁻¹ in the emitting wavelength range of the internally generated light. Most preferably, the absorption coefficient of the multi-layer semiconductor structure is less than 10 cm⁻¹ in the emitting wavelength range of the internally generated light.

In order to achieve the maximum light extraction efficiency of LED 300 and the maximum reflectivity of LED 300 to externally incident light, a low value for the absorption coefficient for the multi-layer semiconductor structure 104 of LED 300 and a high value for the reflectivity of the second reflecting electrode 306 of LED 300 must be present at the same time. In one illustrative example, when the absorption coefficient of the multi-layer semiconductor structure 104 of LED 300 is less than 50 cm⁻¹ in the emitting wavelength range of the internally generated light and simultaneously the reflectivity of the second reflecting electrode 306 is greater than 96 percent in the emitting wavelength range, then the light extraction efficiency of LED 300 into air can be greater than 40 percent and the reflectivity of LED 300 to externally incident light can be greater than 60%.

In a second illustrative example, when the absorption coefficient of the multi-layer semiconductor structure 104 of LED 300 is less than 25 cm⁻¹ in the emitting wavelength range of the internally generated light and simultaneously the reflectivity of the second reflecting electrode 306 is greater than 96 percent in the emitting wavelength range, then the light extraction efficiency of LED 300 into air can be greater than 50 percent and the reflectivity of LED 300 to externally incident light can be greater than 65%.

In a third illustrative example, when the absorption coefficient of the multi-layer semiconductor structure 104 of LED 300 is less than 10 cm⁻¹ in the emitting wavelength range of the internally generated light and simultaneously the reflectivity of the second reflecting electrode 306 is greater than 96 percent, then the light extraction efficiency of LED 300 into air can be greater than 55 percent and the reflectivity of LED 300 to externally incident light can be greater than 70%.

Another embodiment of this invention is LED 400, illustrated in plan view in FIG. 4A. A cross-sectional view in the I-I plane of the LED 400 indicated in FIG. 4A is illustrated in FIG. 4B. LED 400 is another example of an LED that has high reflectivity to externally incident light and high light extraction efficiency for internally generated light, but does not require a transparent overcoat element in order to achieve high light extraction efficiency.

LED 400 includes a first reflecting electrode 102, a multi-layer semiconductor structure 104 and a second reflecting electrode 406. The first reflecting electrode 102 and the multi-layer semiconductor structure 104 have been described previously for LED 100. The second reflecting electrode 406 can be a single metal layer (as illustrated in FIG. 4B), a two-layer structure that includes a first transparent layer and a metal layer, or a three-layer structure that includes a first transparent layer, a second transparent layer and a metal layer.

LED 400 is similar to LED 300 except that the array of light extracting elements 402 is an array of lenses fabricated in the output surface 128 of the first doped semiconductor layer 108. The array of light extracting elements 402 extends at least part way through the multi-layer semiconductor structure 104. In FIGS. 4A and 4B, the array of light extracting elements 402 is an array of hemispherical lenses that have equal heights. The array of lenses is illustrated to have a regular pattern. It is also within the scope of this invention that lenses in the array of lenses can be, for example, hemispherical lenses, convex lenses or concave lenses. The array of lenses may have a regular pattern or the array of lenses may have an irregular pattern. Each lens in the array of lenses may have the same size and shape or each lens in the array of lenses may have varying sizes and shapes.

The array of lenses can cover all of output surface 128 of the first doped semiconductor layer 108 except for the area of the surface 130 of the reflecting electrode 102. Alternatively, the array of lenses can cover only part of the first or output surface 128 of the first doped semiconductor layer 108. Any part of surface 120 not covered with lenses can be a planar surface. The array of lenses extends at least part way through the multi-layer semiconductor structure 104. For example, the array of lenses can extend part way or completely through the first doped semiconductor layer 108. Alternatively, the array of lenses can extend completely through the first doped semiconductor layer 108 and part way or completely though the active region 110. As a another example, the array of lenses can extend completely through both the first doped semiconductor layer 108 and the active region 110 and part way or completely though the second doped semiconductor layer 112. However, the electrical conductivity of the first doped semiconductor layer 108 must be maintained so that the first doped semiconductor layer 108 can function to spread electrical current from the first reflecting electrode 102 the to the entire active region 110. If the entire surface 128 of the first doped semiconductor layer is covered by the array of light extracting elements 402, then preferably the array of light extracting elements extends only part way through the first doped semiconductor layer 108.

The following EXAMPLES further illustrate the embodiments of this invention.

### EXAMPLE 1

A non-sequential ray tracing computer program was used to model the light extraction efficiency of a GaN LED and the reflectivity of the LED to externally incident light. The GaN LED incorporated an array of square pyramids on the output surface for enhanced light extraction. The pyramids each had a 1-micron by 1-micron base and a height of 1 micron. The computer model included the effects of Fresnel reflections at the principal interfaces where the refractive index changed and included the effects of absorption in the semiconductor materials. The GaN was assumed to have a refractive index of 2.50. The 4-micron thick GaN multi-layer semiconductor structure was modeled as a uniform single layer that had a uniform absorption coefficient. The absorption coefficient was varied from 1 cm⁻¹ to 200 cm⁻¹. The bottom side of the multi-layer semiconductor structure was covered with a reflecting electrode. The reflecting electrode was a specular reflector. The reflecting electrode was a metal layer, a two-layer structure that included a first transparent layer and a metal layer, or a three-layer structure that included a first transparent layer, a second transparent layer and a metal layer. The reflectivity of the reflecting electrode was varied from 92% to 99%. The topside of the GaN layer was the output side of the LED and was in contact with air having a refractive index of 1.0. A top electrode was not included in the model.

For light extraction modeling, the light source was an isotropic emitter embedded in the GaN. For light reflection modeling, the light source was a Lambertian (plus or minus 90 degrees) emitter located outside the LED and directed toward the top output surface of the LED.

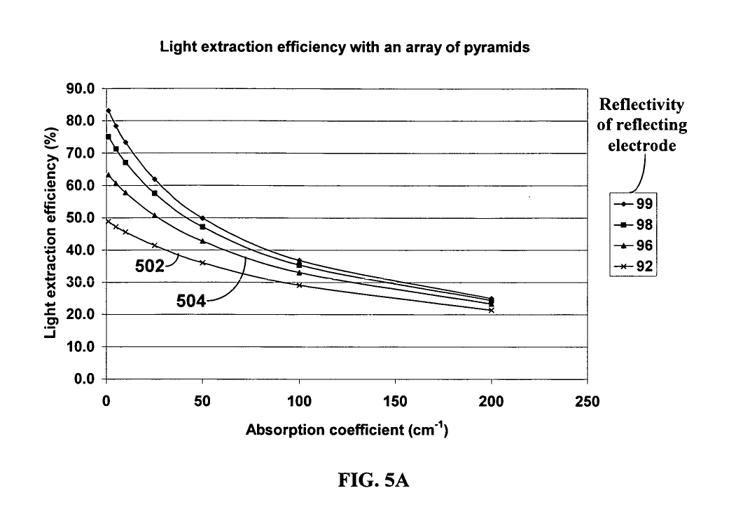

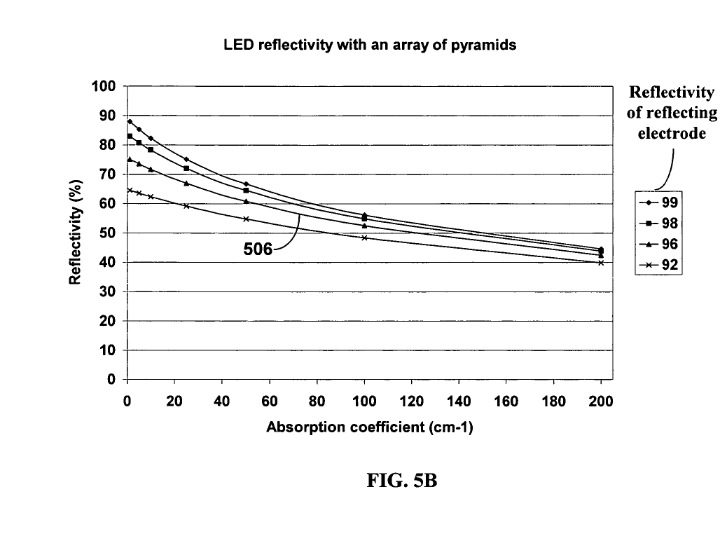

The modeling results for light extraction efficiency are shown in FIG. 5A as a function of the absorption coefficient of the multi-layer semiconductor structure and as a function of the reflectivity of the reflecting electrode. In general, when the absorption coefficient was greater than 100 cm⁻¹, the light extraction efficiency was not strongly affected by changing the reflectivity of the reflecting electrode from 92% to 99%. However, as the absorption coefficient of the multi-layer semiconductor structure was reduced from 100 cm⁻¹ to 1 cm⁻¹, the reflectivity of the reflecting electrode had a greater effect on the light extraction efficiency.

Curve 502 shows the light extraction efficiency when the reflecting electrode had a reflectivity of 92%. When the absorption coefficient was 50 cm⁻¹, the extraction efficiency was 36%. When the absorption coefficient was 25 cm⁻¹, the extraction efficiency was 41%. When the absorption coefficient was 10 cm⁻¹, the extraction efficiency was 46%. Lowering the absorption coefficient improved the extraction efficiency.

Curve 504 shows the light extraction efficiency when the reflecting electrode had a reflectivity of 96%. When the absorption coefficient was 50 cm⁻¹, the extraction efficiency was 43%. When the absorption coefficient was 25 cm⁻¹, the extraction efficiency was 51%. When the absorption coefficient was 10 cm⁻¹, the extraction efficiency was 58%. Lowering the absorption coefficient improved the extraction efficiency. In addition, increasing the reflectivity of the reflecting electrode from 92% to 96% significantly improved the extraction efficiency when the absorption coefficient was less than 100 cm⁻¹.

The modeling results for LED reflectivity to externally incident light are shown in FIG. 5B as a function of the absorption coefficient of the multi-layer semiconductor structure and as a function of the reflectivity of the bottom reflecting electrode. In general, when the absorption coefficient was greater than 100 cm⁻¹, the LED reflectivity was not strongly affected by changing the reflectivity of the reflecting electrode from 92% to 99%. However, as the absorption coefficient of the multi-layer semiconductor structure was reduced from 100 cm⁻¹ to 1 cm⁻¹, the reflectivity of the reflecting electrode had a greater effect on the LED reflectivity.

Curve 506 shows the LED reflectivity when the reflecting electrode had a reflectivity of 96%. When the absorption coefficient was 50 cm⁻¹, the LED reflectivity was 61%. When the absorption coefficient was 25 cm⁻¹, the LED reflectivity was 67%. When the absorption coefficient was 10 cm⁻¹, the LED reflectivity was 72%. Lowering the absorption coefficient improved the LED reflectivity as well as the extraction efficiency.

### EXAMPLE 2

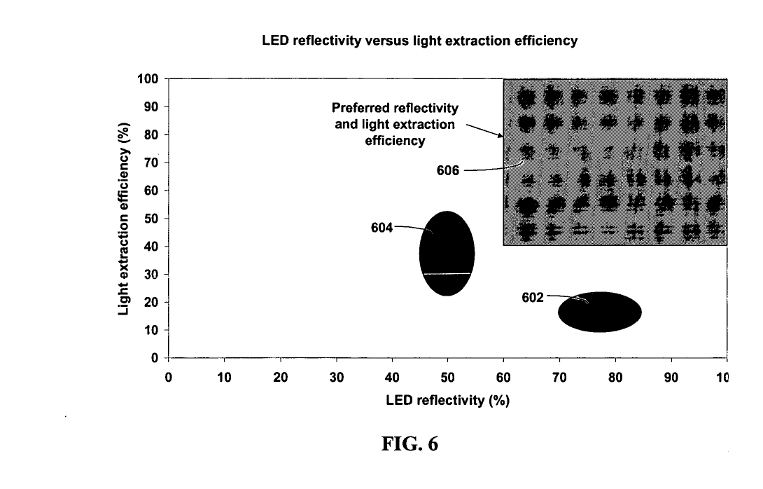

In this example, the reflectivity and extraction efficiency of commercially available LEDs are compared to the preferred embodiments of this invention illustrated in Example 1. Referring to FIG. 6, GaN-based LEDs fabricated on sapphire substrates and manufactured by Lumileds under the product name Luxeon V™ have values of reflectivity and extraction efficiency approximately in the range bounded by the shaded area 602. For example, a Luxeon V™ Lambertian emitter that is not encapsulated with a polymer overcoat has a reflectivity of approximately 70% to 85% (depending on the wavelength of the reflected light) and extraction efficiency estimated to be approximately 10%. A Luxeon V™ Lambertian emitter that is encapsulated with a dome of polymer has a reflectivity of approximately 70% to 85% (depending on the wavelength of the reflected light) and extraction efficiency estimated to be approximately 20%. The Luxeon V™ Lambertian emitters have relatively high reflectivity, but at the expense of low extraction efficiency.

Again referring to FIG. 6, GaN-based LEDs fabricated on silicon carbide substrates and manufactured by Cree Inc. under the product name XB900™ have values of reflectivity and extraction efficiency approximately in the range bounded by the shaded area 604. For example, an XB900™ LED that is not encapsulated with a polymer overcoat has a reflectivity of approximately 50% and extraction efficiency estimated to be approximately 25%. An XB900™ LED that is encapsulated with a dome of polymer has a reflectivity of approximately 50% and extraction efficiency estimated to be approximately 50%. The Cree LEDs have improved extraction efficiency compared to Lumileds Luxeon V™ but at the expense of lower reflectivity.

In Example 1 above, preferred embodiments of this invention are illustrated that simultaneous have preferred reflectivity values of greater than 60% and preferred extraction efficiencies of greater than 40%. In FIG. 6, the preferred embodiments lie within the shaded area 606. The preferred embodiments of this invention are useful for applications in which light is recycled back to the LED light source or for applications requiring low profile LEDs that do not have a polymer overcoat or lens.

While the invention has been described in conjunction with specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

What is claimed is:

1. A light emitting diode comprising:
a multi-layer semiconductor structure having a first doped semiconductor layer, an active region and a second doped semiconductor layer, said first doped semiconductor layer and said second doped conductivity layer having opposite n and p conductivity types;
an array of light extracting elements on a first portion of said first doped semiconductor layer extending at least partially into said multi-layer semiconductor structure, said array of light extracting elements transmitting externally incident light into said multi-layer semiconductor structure or transmitting the externally incident light from said multi-layer semiconductor structure;
a first reflecting electrode on a second portion of said first doped semiconductor layer, said second portion of said first doped semiconductor layer being different from said first portion of said first doped semiconductor layer, said first reflecting electrode reflecting the externally incident light;
a second reflecting electrode on said second doped semiconductor layer, said second reflecting electrode reflecting the externally incident light transmitted through said multi-layer semiconductor structure, wherein said second reflecting electrode has a first transparent layer and a reflecting metal layer and wherein said first transparent layer is between said reflecting metal layer and said second doped semiconductor layer;
wherein said active region emits internally generated light in an emitting wavelength range when a voltage is applied between said first reflecting electrode and said second reflecting electrode; said internally generated light being either emitted through said array of light extracting elements, reflected by said first reflecting electrode or reflected by said second reflecting electrode; and
wherein said multi-layer semiconductor structure has an absorption coefficient less than 50 cm⁻¹ in the emitting wavelength range of the internally generated light and wherein said light emitting diode reflects the externally incident light with a reflectivity greater than 60 percent.

2. The light emitting diode of claim 1 further comprising:
a second transparent layer in said second reflecting electrode wherein said second transparent layer is between said first transparent layer and said second doped semiconductor layer.

3. The light emitting diode of claim 2 further comprising:
a plurality of contacts in said second reflecting electrode extending from said reflecting metal layer through said first transparent layer to said second transparent layer.

4. The light emitting diode of claim 1 wherein said first transparent layer is a dielectric material.

5. The light emitting diode of claim 4 wherein said dielectric material is silicon dioxide, silicon nitride or magnesium fluoride.

6. The light emitting diode of claim 1 wherein said first transparent layer is a transparent conductive oxide.

7. The light emitting diode of claim 6 wherein said transparent conductive oxide is indium tin oxide, ruthenium oxide, copper doped indium oxide or aluminum doped zinc oxide.

8. The light emitting diode of claim 6 wherein said transparent conductive oxide is porous.

9. The light emitting diode of claim 1 wherein said reflecting metal layer is silver or aluminum.

10. The light emitting diode of claim 1 wherein said multi-layer semiconductor structure is formed by hydride vapor phase epitaxy.

11. The light emitting diode of claim 1 wherein said array of light extracting elements is an array of pyramids.

12. The light emitting diode of claim 3 wherein said second transparent layer is a transparent conductive oxide.

13. The light emitting diode of claim 1 wherein said first reflecting electrode has a transparent layer and a reflecting metal layer and wherein said transparent layer is between said reflecting metal layer and said first doped semiconductor layer.

14. The light emitting diode of claim 11 further comprising:
a plurality of contacts in said first reflecting electrode extending from said reflecting metal layer through said transparent layer to said first doped semiconductor layer.

15. The light emitting diode of claim 1 wherein said first reflecting electrode and said second reflecting electrode are on opposite sides of said light emitting diode.

16. The light emitting diode of claim 1 wherein said first reflecting electrode and said second reflecting electrode are on the same side of said light emitting diode.
